(19) United States
(12) Patent Application Publication
(10) Pub. No.: US 2010/0071751 A1
(43) Pub. Date: Mar. 25, 2010

(54) PHOTO-INDUCED METAL-INSULATOR-TRANSITION MATERIAL COMPLEX FOR SOLAR CELL, SOLAR CELL AND SOLAR CELL MODULE COMPRISING THE SAME

(75) Inventors: Hyun Tak KIM, Daejeon-City (KR); Bongjun KIM, Daejeon-City (KR); Sun Jin YUN, Daejeon-City (KR); Byung Gyu CHAE, Daejeon-City (KR); Jung Wook LIM, Daejeon-City (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon-City (KR)

(21) Appl. No.: 12/564,839

(22) Filed: Sep. 22, 2009

(30) Foreign Application Priority Data
Sep. 22, 2008 (KR) 10-2008-0092945
Dec. 15, 2008 (KR) 10-2008-0127267

(51) Int. Cl. H01L 31/042; H01L 31/00

(52) U.S. Cl. 136/244; 136/256; 252/501.1

(57) ABSTRACT

Provided are a photo-induced metal-insulator-transition (MIT) material complex for a solar cell which can be used to manufacture highly efficient solar cells with more carriers than an impurity solar cell, and a solar cell including the MIT material complex, and a solar cell module. The solar cell includes: a substrate; a lower electrode formed on the substrate; a photo-induced MIT material complex formed on the lower electrode, wherein electrons and holes are formed when light is incident on n-type and p-type metal conductors that are bonded to each other, and the electrons and holes in an intrinsic energy level or gap become carriers, and a potential difference is generated; an anti-reflection layer formed on the MIT material complex; and an upper electrode that is formed to pass through the anti-reflection layer and to contact the MIT material complex. The n-type and p-type metal conductors are MIT materials which are insulators (or semiconductors) that have a metallic electronic structure at room temperature and also intrinsic energy levels, and an odd number of electrons or holes are in their outermost electron shell of the metallic electronic structure of the MIT materials. When an intrinsic energy level of the solar cell is broken, a greater number of carriers are induced than the number of carriers induced from an impurity level of a semiconductor. Accordingly, the solar cell has more carriers than carriers induced from an impurity level of a semiconductor solar cell.

### CROSS-REFERENCE TO RELATED PATENT APPLICATION

This application claims the benefits of Korean Patent Application No. 10-2008-0092945, filed on Sep. 22, 2008 and No. 10-2008-0127267, filed on Dec. 15, 2008, in the Korean Intellectual Property Office, the disclosures of which are incorporated herein in their entirety by reference.

### BACKGROUND OF THE INVENTION

1. Field of the Invention

The present invention relates to a solar cell that uses a metal-insulator-transition (MIT) material, and more particularly, to a high efficiency solar cell using MIT generated by light.

2. Description of the Related Art

In a battery that stores energy generated from sunlight, that is, a solar cell, when light is incident on a junction portion of a p (hole)-type semiconductor and an n (electron)-type semiconductor, electrons and holes are generated and charges are gathered at both electrodes by a contact potential difference generated in the junction portion of the two semiconductors. While an intrinsic semiconductor is a complete insulator, an impurity semiconductor has an impurity level and charges of electrons or holes of about 5×10¹⁸ cm⁻³. The solar cells cannot use all of the charges when generating electricity because it is difficult to turn the charges of the semiconductor into carriers by using only a small contact voltage obtained through sunlight.

In detail, a conventional solar cell has a structure including a substrate or crystals, a lower electrode, a p-type impurity semiconductor, an n-type impurity semiconductor, an anti-reflection layer, and an upper electrode. When light arrives at the solar cell, electrons are excited to a conduction band and holes are excited to a valence band, and a contact voltage is created between the p-type impurity semiconductors and the n-type impurity semiconductors. Accordingly, charges that are induced by light gather at both electrodes and when a load is connected between both electrodes from the outside, current flows and the solar cell functions as a battery.

The conventional solar cells are p-n junction batteries that use impurity levels of semiconductors and have predetermined efficiencies. However, the power efficiency thereof is not high compared to the installation costs, and thus, it takes a long time to reach a break-even point. Thus, more efficient solar cells need to be developed.

To overcome the problem of efficiency, research has been conducted on the material and structure of batteries. For example, Si-based solar cells, Group III-V compound solar cells, Group II-VI CdTe-based or CIGS (Ca, In, Ga, Se)-based solar cells are developed. However, these solar cells use an impurity level of a semiconductor and thus have limits in terms of efficiency. Accordingly, a new principle of forming solar cells so as to have high efficiency is required.

### SUMMARY OF THE INVENTION

The present invention provides a photo-induced metal-insulator-transition (MIT) material complex which can be used in the manufacture of a high efficiency solar cell that has more carriers compared to an impurity semiconductor solar cell, a solar cell including the photo-induced MIT material complex, and a solar cell module.

According to an aspect of the present invention, there is provided a photo-induced metal-insulator-transition (MIT) material complex for a solar cell, the photo-induced MIT material complex comprising: an n-type (or electron-type) metal conductor that has a metallic electronic structure and undergoes MIT due to light, wherein carriers of the n-type metal conductor are electrons induced by light; and a p-type (hole type) metal conductor that has a metallic electronic structure and undergoes MIT due to light, wherein carriers of the p-type metal conductor are holes induced by light, wherein the photo-induced MIT material complex is formed by bonding the n-type and p-type metal conductors, and as light is incident on the bonded n-type and p-type metal conductors, the electrons and holes in an intrinsic energy level or gap become the carriers and a potential difference is generated.

The p-type metal conductor may be formed by stacking at least two p-type metal conductor thin films having different intrinsic energy levels, and the n-type metal conductor may be formed by stacking at least two n-type metal conductor thin films having different intrinsic energy levels. The p-type metal conductor may be a compound including Group I+VI elements or Group II+V elements of the periodic table, and the n-type metal conductor may be a compound including Group III+VI elements or Group IV+V elements of the periodic table. The p-type metal conductor and the n-type metal conductor may be formed of various elements that are bonded to one another. For example, the p-type metal conductor may comprise at least one of La₂CuO₄, Ce₂CuO₄, Sc₂CuO₄, Y₂CuO₄, Ce₂CuSe₄, Sc₂CuSe₄, Y₂CuSe₄, Ce₂CuTe₄, Sc₂CuTe₄, and Y₂CuTe₄. The n-type metal conductor may comprise at least one of VO₂, BaBiO₃, and LaMnO₃.

According to another aspect of the present invention, there is provided a solar cell comprising: a substrate; a lower electrode formed on the substrate; the above-described photo-induced MIT material complex formed on the lower electrode; an anti-reflection layer formed on the MIT material complex; and an upper electrode that is formed to pass through the anti-reflection layer and to contact the MIT material complex.

The MIT material complex may be formed on the lower electrode in the order of the n-type metal conductor and the p-type metal conductor or in the order of the p-type metal conductor and the n-type metal conductor. Also, the MIT material complex may further comprise a buffer layer between the n-type metal conductor and the p-type metal conductor. When the buffer layer is formed, the buffer layer may comprise a compound including at least one of Group II+VI, Group III+V, and Group IV elements of the periodic table, or a Group 2I+VI metal compound of the periodic table, or a Group 2III+3VI metal compound of the periodic table.

The anti-reflection layer may comprise at least two anti-reflection thin films formed of different materials. The anti-reflection layer may comprise at least one of a transparent compound, ZnO, TiO₂, BaTiO₃, and ZrO₂, which have an energy level of 3 eV or greater. The substrate may comprise one of Si, glass, a stainless iron plate, a silicon-on-insulator (SOI), and a compound substrate, and the lower and upper electrodes may comprise a monoatomic metal electrode or a compound electrode.

According to another aspect of the present invention, there is provided a solar cell comprising: a substrate; a lower electrode formed on the substrate; a photo-induced MIT material complex to be used to form a solar cell, which is formed on the lower electrode and comprises an n-type metal conductor and a p-type metal conductor; an anti-reflection layer formed on the MIT material complex; and an upper electrode that is formed to pass through the anti-reflection layer and to contact the MIT material complex, wherein the n-type metal conductor has no intrinsic energy level and carriers of the n-type metal conductor are pure electrons, and the p-type metal conductor is an insulator or semiconductor that has a metallic electronic structure and undergoes MIT due to light, and has an intrinsic energy level, and carriers of the p-type metal conductor are holes induced by light, and the MIT material complex is formed by bonding the n-type and p-type metal conductors, and as light is incident on the n-type and p-type metal conductors, the pure electrons and the holes in the intrinsic energy level become the carriers and a potential difference is generated.

According to another aspect of the present invention, there is provided a solar cell module which is formed of at least two of the above solar cell, wherein the solar cells are connected serially.

All of the solar cells of the solar cell module may be arranged on the substrate, and the lower electrodes of the solar cells may be separated from one another by a portion of the p-type metal conductor or a portion of the n-type metal conductor of the MIT material complex, which is extended onto the substrate, and the MIT material complexes in each of the solar cells may be separated from one another by a predetermined portion of the anti-reflection layer, which is extended onto the lower electrodes, and structures formed on the lower electrodes may be separated by a predetermined distance apart from one another to separate the solar cells in the solar cell module from one another, and the solar cells may be serially connected via the lower electrodes.

The solar cell may be one of a solar cell including a glass substrate/Ni (or Mo, Al)/CuSe/Cu₂Se/GaSe/InSe/ZnO (or transparent layer)/Au (or Al) that are sequentially formed, a solar cell including a glass substrate/Ni (or Mo, Al)/CuTe/Cu₂Te/GaSe/InSe/ZnO (or transparent layer)/Au (or Al) that are sequentially formed, a solar cell including a glass substrate/Ni (or Mo, Al)/CuTe/Cu₂Te/GaSe/CdS/ZnO (or transparent layer)/Au (or Al) that are sequentially formed, a solar cell including a glass substrate/Ni (or Mo, Al)/CuS/Cu₂S/CdS/ZnO (or transparent layer)/Au (or Al) that are sequentially formed, and a solar cell including a glass substrate/Ni (or Mo, Al)/CuTe/Cu₂Te/CdS/ZnO (or transparent layer)/Au (or Al) that are sequentially formed.

### BRIEF DESCRIPTION OF THE DRAWINGS

The above and other features and advantages of the present invention will become more apparent by describing in detail exemplary embodiments thereof with reference to the attached drawings in which:

FIG. 1 is a graph illustrating optical conductivity spectrums of BaBiO₃ which has a metallic electronic structure, impurity levels, and an intrinsic energy level;

FIG. 2 is a graph illustrating a theory model showing a metal-insulator-transition (MIT) that occurs when a small density of holes are added to a Mott insulator having a metallic electronic structure;

FIG. 3 is a graph illustrating luminescence that is generated as light is incident on Be—GaAs which is an MIT material;

FIG. 4 is a perspective view of a photo-induced MIT material complex for a solar cell according to an embodiment of the present invention;

FIGS. 5A and 5B are cross-sectional views illustrating solar cells including a photo-induced MIT material complex according to embodiments of the present invention;

FIG. 6 is a cross-sectional view illustrating a solar cell including a photo-induced MIT material complex according to another embodiment of the present invention;

FIG. 7 is a cross-sectional view illustrating a solar cell including a photo-induced MIT material complex according to another embodiment of the present invention;

FIG. 8 is a cross-sectional view illustrating a solar cell including a photo-induced MIT material complex according to another embodiment of the present invention; and

FIG. 9 is a cross-sectional view illustrating a solar cell module including a photo-induced MIT material complex according to an embodiment of the present invention.

### DETAILED DESCRIPTION OF THE INVENTION

In general, an insulator or a semiconductor is classified into two types; general insulators have charges that fill an orbit, whereas some insulators or semiconductors have a metallic electronic structure but are not metals. The insulator or the semiconductor having a metallic electronic structure has an intrinsic energy level or gap and undergoes a metal-insulator-transition (MIT). Hereinafter, the insulator or the semiconductor that has a metallic electronic structure and undergoes MIT is referred to as an ‘MIT material’. In the MIT material, charges of the intrinsic energy level induced by light may function as carriers. Thus, the MIT material may be used in solar cells.

The present invention provides a solar cell that is realized by using a photo-induced MIT occurring in an MIT material, whereby a number of carriers are generated. This is a new principle related to solar cells.

The present invention will now be described more fully with reference to the accompanying drawings, in which exemplary embodiments of the invention are shown. It will be understood that when a layer is referred to as being “on” another layer or substrate, it can be directly on the other layer or substrate, or intervening layers may also be present. In the drawings, the thicknesses of layers and regions are exaggerated for clarity, and elements not related to the description are omitted. Like reference numerals in the drawings denote like elements, and thus their description will be omitted. The terminology used herein is for the purpose of describing particular embodiments only and is not intended to be limiting of exemplary embodiments. Also, in regard to the description, if a description of a relevant, well-known function or structure of elements may make the essence of the present invention vague, the description thereof will be omitted.

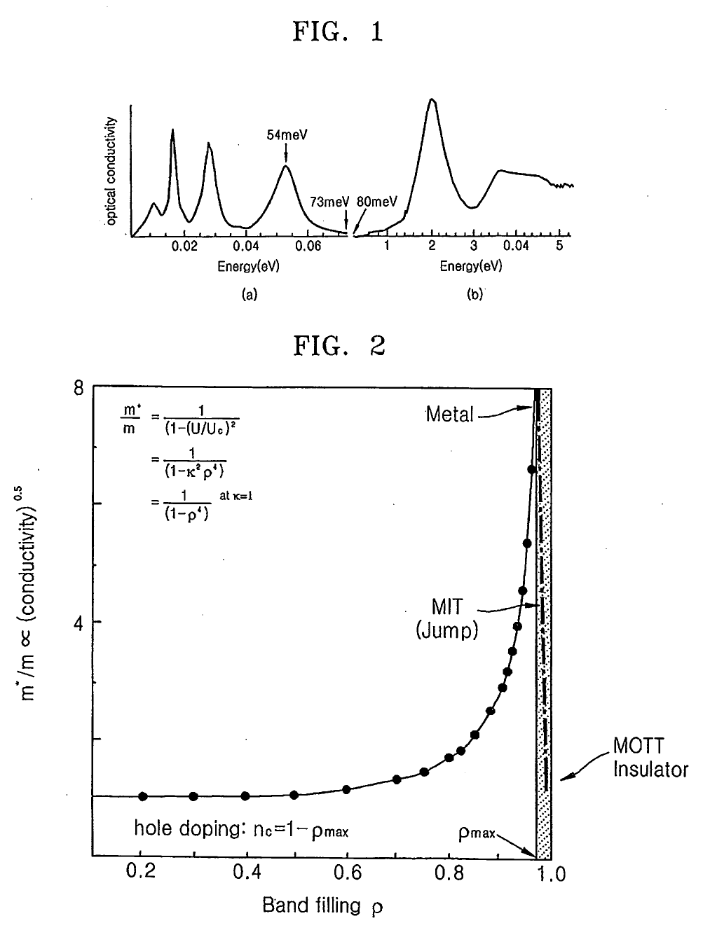

FIG. 1 illustrates graphs of optical conductivity spectrums of BaBiO₃ which has a metallic electronic structure, impurity levels and an intrinsic energy level. Four peaks in (a) illustrate impurity levels of BaBiO₃, and a large peak of around 2 eV in (b) refers to the intrinsic energy level of BaBiO₃.

The electronic structure of BaBiO₃ (BBO), which has a metallic electronic structure, and impurity levels and an intrinsic energy level, will be described in detail with reference to FIG. 1.

Regarding BaBiO₃(Ba⁺², Bi⁺⁴, O⁻²), Ba contains two electrons in an outermost electron shell, Bi contains five electrons in an outermost electron shell, and O contains two holes in an outermost electron shell, which means that two electrons are lacking. Thus, valence electrons of BaBiO₃ are bonded in the manner 2 (of Ba)+4 (of Bi)−6 (−2×3 of O), and one electron is left in Bi. Accordingly, BaBiO₃ has a metallic electronic structure. However, BaBiO₃ is not a metal but a semiconductor or an insulator that has an impurity level (see portion (a) of FIG. 1) and an intrinsic energy level of 2 eV (see portion (b) of FIG. 1) in a low energy level at room temperature.

Another example of the semiconductor or insulator having a metallic electronic structure is VO₂ (V⁺⁴, O⁻²). Vanadium (V) has five electrons in an outermost electron shell, and thus when it is bonded to oxygen, four electrons are used, and one electron is left in the outermost electron shell. Accordingly, VO₂ also has a metallic electronic structure. Although not illustrated in the drawing, VO₂ is a semiconductor or insulator having an intrinsic energy level of 1 eV.

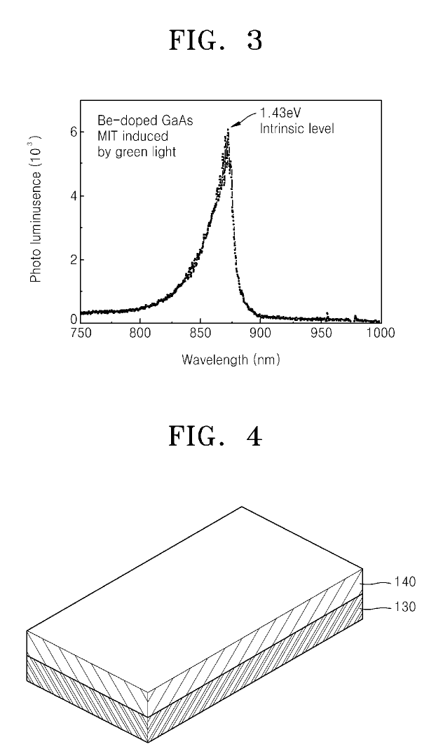

Since the metallic electronic structure is defined as a structure including a carrier of one outermost electron (or hole) of one element, the intrinsic energy level refers to a potential well where the carrier is confined. The intrinsic energy level theoretically includes charges (electrons or holes) of 1×10²² cm⁻³or greater. Also, when the intrinsic energy level or gap is destroyed by light, light corresponding to the energy gap is emitted. This will be described in more detail with reference to FIG. 3.

As described above, in FIG. 1, (a) refers to the impurity level of BaBiO₃, and when an area of the impurity level of BaBiO₃ is integrated, holes of 5×10¹⁸ cm⁻³ may be obtained. Also, (b) of FIG. 1 corresponds to the intrinsic energy level of BaBiO₃, and when a peak of around 2 eV of BaBiO₃ is integrated, electrons of about 1×10²¹ cm⁻³ or more may be obtained.

In general, a compound insulator or semiconductor having the metallic electronic structure contains both the impurity level and the intrinsic energy level. Thus, if more charges of the intrinsic energy level than charges of the impurity level are used as carriers of a solar cell, the efficiency of the solar cell can be increased significantly.

FIG. 2 is a graph illustrating an MIT theory model when a small density of holes are added to a Mott insulator having a metallic electronic structure.

Referring to FIG. 2, when a small density of holes (or electrons) are added to a Mott insulator having a metallic electronic structure, MIT occurs. That is, when a small density of holes (or electrons) are added to a Mott insulator having a metallic electronic structure, charges of the intrinsic energy level may be excited more easily, and thus, the MIT occurs. In FIG. 2, a hatched portion indicates a semiconductor area between a metal and a Mott insulator.

However, when the density of charges (electrons or holes) to be added is larger than ρₘₐₓ, the electrical conductivity is decreased, thereby abruptly decreasing the metal characteristics. In order to manufacture a solar cell, an amount of added holes ρ should be ρ<ρₘₐₓ. Here, ρₘₐₓ is a critical density ρ_{critical}, and (ρ_{critical})^{1/3}A_{B□}0.25. A_{B} is a Bohr radius and is defined in a predetermined material. ρ_{critical} of VO₂ is known to be approximately 3×10¹⁸ cm⁻³.

The insulator or semiconductor having the metallic electronic structure undergoes an MIT, and is referred to as an MIT material as described above. Also, the MIT material may be classified as an n-type MIT material and a p-type MIT material according to the type of carriers.

When light is irradiated to the MIT material, charges in the intrinsic energy level of around 2 eV as shown in (b) of FIG. 1 are induced as carriers (free electrons). An insulator or semiconductor having a metallic electronic structure such as a Mott insulator is more sensitive to light than an insulator or semiconductor having an electronic structure of an insulator that fills an outermost electron orbital completely.

Hereinafter, materials for insulators that are ion-bonded and have an electronic structure that completely fills the outermost orbital will be described. These insulators are well known and are used for all kinds of solar cells. Accordingly, regarding a compound containing a monovalent (Group I) metal and a six-valent (Group VI) metal, a compound including Groups 2I+VI may be used. For example, compounds such as Cu₂S, Ag₂S, Cu₂Se, Ag₂Se, Cu₂Te, and Ag₂Te are obtained.

Meanwhile, regarding a compound containing a tri-valent (Group III) metal and a six-valent (Group VI) metal, a compound including Groups 2III+3VI may be used. Examples of the compound are B₂S₃, Al₂S₃, Ga₂S₃, B₂Se₃, Al₂Se₃, Ga₂Se₃, In₂Se₃, B₂Te₃, Al₂Te₃, Ga₂Te₃, and In₂Te₃. Also, compounds of metals of Group II+VI, Group III+V, and Group IV may also be possibly used as insulators. These insulators or semiconductors that completely fill an orbital may be used as a buffer layer of a solar cell according to the present invention, and will be described in more detail later.

As described above with respect to BaBiO₃, the number of charges (electrons or holes) in the impurity level in a semiconductor is 5×10¹⁸ cm⁻³ at maximum, but the number of charges in the intrinsic energy level is about 10²² cm⁻³ or more. Accordingly, it is effective to use the intrinsic energy level to manufacture a more efficient solar cell. An MIT solar cell uses carriers induced from the intrinsic energy level when light is incident on an MIT material or Mott insulator described above, and this principle is referred to as a photo-induced MIT.

FIG. 3 is a graph illustrating a principle of luminescence that is generated as light is incident on Be—GaAs, which is an MIT material.

As illustrated in FIG. 3, green light is incident on Be—GaAs which is an MIT material to which Be is added and thus the intrinsic energy level thereof is destroyed, and light corresponding to the intrinsic energy level is emitted. In other words, luminescence is generated. The intrinsic energy level is 1.43 eV, and a wavelength of emitted light is about 870 nm, corresponding to the intrinsic energy level. Consequently, such an occurrence is a sign that light destroys the intrinsic energy level of an MIT material directly. The solar cell according to the present invention uses this phenomenon. That is, according to the present invention, light incident on the MIT material destroys the intrinsic energy level, and charges in the intrinsic energy level are used as carriers for the solar cell.

FIG. 4 is a perspective view of a photo-induced MIT material complex for a solar cell according to an embodiment of the present invention.

Referring to FIG. 4, the photo-induced MIT material complex for a solar cell according to the current embodiment of the present invention has a structure in which a p-type metal conductor 130 and an n-type metal conductor 140 are combined with each other. The p-type metal conductor 130 has a metallic electronic structure and is an insulator or semiconductor that undergoes an MIT due to light, in which carriers are holes induced by light. That is, the p-type metal conductor 130 is one of the above-described p-type MIT materials. Also, the n-type metal conductor 140 has a metallic electronic structure and is an insulator or semiconductor that undergoes an MIT due to light, in which carriers are electrons induced by light. That is, the n-type metal conductor 140 is one of the above-described n-type MIT materials.

In the photo-induced MIT material complex in which the p-type metal conductor 130 and the n-type metal conductor 140 are combined, the intrinsic energy level is broken by light or a p-n junction voltage is created by carriers induced from the intrinsic energy level. When the intrinsic energy level is broken, the number of induced carriers is far greater than the number of carriers induced from the impurity level of a semiconductor. Thus, when the photo-induced MIT material complex according to the current embodiment of the present invention is used in solar cells, solar cells having a higher efficiency than solar cells using an impurity semiconductor may be realized.

Hereinafter, the MIT material will be described in detail.

An example of the MIT materials, that is, insulators or semiconductor having a metallic electronic structure can be obtained by bonding elements as a compound in the periodic table. For example, the MIT material is obtained by bonding a tri-valent element (Group III, including three electrons in the outermost electron shell) and a six-valent element (Group VI, minus bivalent, including six electrons in the outermost electron shell and lacking two electrons, which means that two holes are present). That is, the MIT material is a compound having a metallic electronic structure with one electron in the outermost electron shell of the tri-valent element. The compound is an electron type (n-type) metal conductor which has carriers induced by light, wherein the carriers are electrons. Among these compounds are materials having an intrinsic energy level. Examples of the compounds of Group III+VI include BS, AlS, GaS, InS, BSe, AlSe, GaSe, InSe, BTe, AlTe, GaTe, and InTe. Another example of the n-type metal conductor is a compound including elements of Groups IV+V in the periodic table. Also, the electron type metal conductor may be a compound including Group III+VI elements of the periodic table, and a Group II element below a critical density can be added to the compound including Group III+VI elements.

Meanwhile, by bonding a six-valent (Group VI, minus bivalent) metal to a monovalent (Group I) metal, a six-valent metal missing one electron, that is, a hole-type compound having a metallic electronic structure including a surplus hole is formed. The compound is a hole type (p-type) metal conductor having carriers induced by light, wherein the carriers are holes. Among these compounds are materials having an intrinsic energy level. Examples of the compound of Group I+VI are CuS, CuSe, CuTe, AgS, AgSe, and AgTe. Also, the p-type metal conductor may be formed of compounds including Group II+V. Also, the p-type metal conductor may be a compound including Group II+V in the periodic table, and a Group IV element below a critical density can be added to the compounds including Group II+V.

Materials having the MIT material characteristics may also be formed by bonding elements of the periodic table in different manners. For example, La₂CuO₄, Ce₂CuO₄, Sc₂CuO₄, Y₂CuO₄, Ce₂CuSe₄, Sc₂CuSe₄, Y₂CuSe₄, Ce₂CuTe₄, Sc₂CuTe₄, and Y₂CuTe₄ may also be hole type metal conductors. Also, examples of the electron type metal conductors are VO₂, BaBiO₃, and LaMnO₃. Also, many n-type or p-type metal conductors, which are insulators or semiconductors having an n-type or p-type metallic electronic structure, exist in the natural world.

The above-described selection methods of the materials are inferred from the MIT theory illustrated in FIG. 3, in which an insulator is transitioned to a metal when a small density of holes (or electrons) is added to an insulator having an electron type (or hole type) metallic electronic structure. In general, if the Coulomb interaction between free electrons of metals is very large, it is an insulator, and such an insulator is called a Mott insulator. Also, if a charge imbalance is generated between neighboring free charges, insulators may be formed, which are called charge density wave insulators. These insulators having the metallic electronic structure and MIT phenomenon are being continuously researched in modern solid state physics.

The photo-induced MIT material complex for a solar cell according to the current embodiment of the present invention may further include a buffer layer (not shown) between the p-type metal conductor 130 and the n-type metal conductor 140 in order to reduce a lattice mismatch between the p-type metal conductor 130 and the n-type metal conductor 140. The buffer layer may have an electronic structure in which charges of the outermost electron shell are completely filled.

For example, the buffer layer may be the ion-bonded insulator having an electronic structure in which the outermost orbital is completely filled, as described with reference to FIG. 3, that is, the compound including at least one of: elements of Group II+VI, Group III+V, and Group IV; a Group 2I+VI metal compound from the periodic table, that is, a compound including at least one of Cu₂S, Ag₂S, Cu₂Se, Ag₂Se, Cu₂Te, and Ag₂Te; and a Group 2III+3VI metal compound from the periodic table, that is, a compound including at least one of B₂S₃, Al₂S₃, Ga₂S₃, B₂Se₃, Al₂Se₃, Ga₂Se₃, In₂Se₃, B₂Te₃, Al₂Te₃, Ga₂Te₃, and In₂Te₃.

The buffer layer also contributes to light absorption and thus may further increase the efficiency of the solar cell.

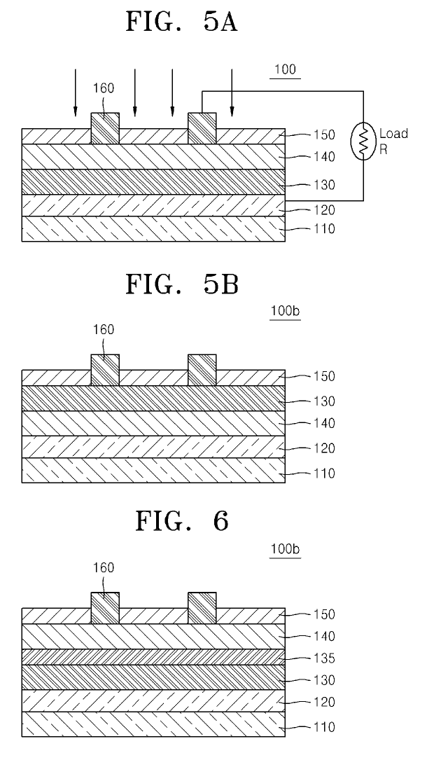

FIGS. 5A and 5B are cross-sectional views illustrating solar cells 100 and 100a including a photo-induced MIT material complex according to embodiments of the present invention.

Referring to FIG. 5A, the solar cell 100 includes a substrate 110, a lower electrode 120, a p-type metal conductor 130, an n-type metal conductor 140, an anti-reflection layer 150, and an upper electrode 160.

The substrate 110 may be formed of at least one of Si, glass, a stainless iron plate, a silicon-on-insulator (SOI), and a compound substrate. Meanwhile, the lower electrode 120 and the upper electrode 160 may be a monoatomic metal electrode or a compound electrode. The lower electrode 120 is formed between the substrate 110 and the p-type metal conductor 130, and the upper electrode 160 is formed to contact the n-type metal conductor 140 through the anti-reflection layer 150.

The p-type metal conductor 130 and the n-type metal conductor 140 are a p-type MIT material and an n-type MIT material, respectively, and may be formed of the materials described with reference to FIG. 4. Also, the p-type metal conductor 130 and the n-type metal conductor 140 are bonded to each other and form a photo-induced MIT material complex which is the core of the solar cell 100.

The anti-reflection layer 150 prevents light from being reflected on an interface and increases light absorption in the solar cell 100. The anti-reflection layer 150 may be formed of at least one of a transparent compound, ZnO, TiO₂, BaTiO₃, and ZrO₂, which have an energy level of 3 eV or greater.

The solar cell 100a illustrated in FIG. 5B is the same as the solar cell 100 except that the order of the p-type metal conductor 130 and the n-type metal conductor 140 is reversed, and has the same characteristics and effects as the solar cell 100.

The solar cell 100 or 100a according to the current embodiment of the present invention functions such that when sunlight is incident on the solar cell 100 or 100a, the light excites charges of intrinsic energy levels of the n-type metal conductor 140 and the p-type metal conductor 130, that is, electrons and holes, to an electron conduction band and a hole valence band. The excited electrons and holes return to the intrinsic energy levels after 10⁻⁸ sec, but since light is continuously incident, they are excited again, and when an external load LOAD R is connected, the excited charges flow and thus, the solar cell 100 or 100a functions as a battery.

Meanwhile, the following facts may preferably be considered when manufacturing solar cells according to the present invention. Sunlight is mainly made up of visible rays, and thus it is preferable to select the MIT materials, that is, the p-type metal conductor and the n-type metal conductor, using materials whose intrinsic energy level is within a spectrum of the visible rays. Also, in this case, an ideal battery may be manufactured by forming a p-type metal conductor by using a material having a p-type impurity energy level and a p-type intrinsic energy level, and an n-type metal conductor by using a material having an n-type impurity level and an n-type intrinsic energy level. The MIT materials are formed on a substrate through deposition to constitute a solar cell. However, solar cells not being the above-described ideal battery also have higher efficiency compared to the conventional impurity semiconductor solar cells. For example, BaBiO₃, which is an n-type metal conductor having a p-type impurity level and an n-type intrinsic energy level may be used to realize high efficiency solar cells.

Furthermore, in order to absorb light of a broader visible light ray spectrum, a p-type metal conductor may be formed by stacking multiple sheets of p-type metal conductor thin films having different intrinsic energy levels, and an n-type metal conductor may be formed by stacking multiple sheets of n-type metal conductor thin films having different intrinsic energy levels. Accordingly, a more efficient solar cell may be formed.

FIG. 6 is a cross-sectional view illustrating a solar cell 100b including a photo-induced MIT material complex according to another embodiment of the present invention.

Referring to FIG. 6, the solar cell 100b is similar to the solar cell 100 of FIG. 5A except that the solar cell 100b further includes a buffer layer 135 between the p-type metal conductor 130 and the n-type metal conductor 140. The buffer layer 135 reduces a lattice mismatch between the p-type metal conductor 130 and the n-type metal conductor 140 and may contribute to increasing light absorption. The buffer layer 135 may be formed of the materials described above with reference to FIG. 4.

Other features of the solar cell 100b are the same as the solar cell 100 or 100a described with reference to FIG. 5A or 5B and thus a description thereof will be omitted here.

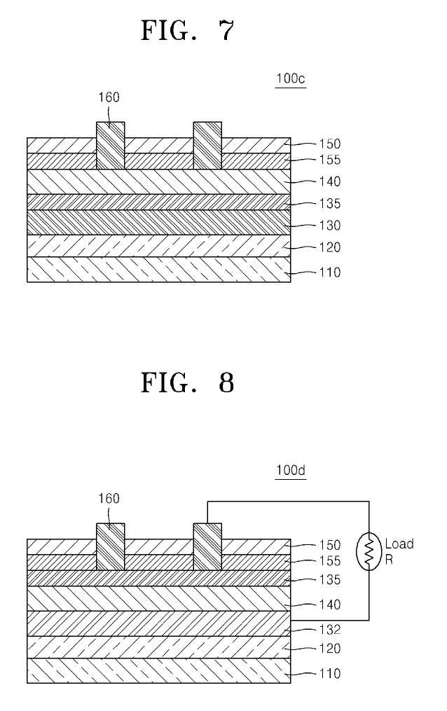

FIG. 7 is a cross-sectional view illustrating a solar cell 100c including a photo-induced MIT material complex according to another embodiment of the present invention.

Referring to FIG. 7, the solar cell 100c is similar to the solar cell 100b of FIG. 6 except that a lower anti-reflection layer 155 is further formed below the anti-reflection layer 150. As the lower anti-reflection layer 155 is further formed, reflection of light incident on an interface is prevented more efficiently, and absorption of light of the solar cell 100c may be increased, thereby increasing the efficiency of the solar cell 100c. In order to increase an anti-reflection effect, the lower anti-reflection layer 155 may preferably be formed of a different material from the anti-reflection layer 150. The anti-reflection layer 150 and the lower anti-reflection layer 155 may be formed of the materials described with reference to FIG. 5A.

Other features of the solar cell 100c are the same as the solar cell 100b described with reference to FIG. 6, and thus a description thereof will be omitted here.

FIG. 8 is a cross-sectional view illustrating a solar cell 100d including a photo-induced MIT material complex according to another embodiment of the present invention.

Referring to FIG. 8, the solar cell 100d is similar to the solar cell 100c of FIG. 7 except that an n-type metal conductor formed of an MIT material is replaced with an n-type metal conductor 132 that has pure electron carriers instead of photo-induced carriers. That is, in the current embodiment, instead of the p-type metal conductor of the MIT material and the n-type metal conductor of the MIT material being combined, the p-type metal conductor of the MIT material and a pure n-type metal conductor are combined to manufacture the solar cell 100d. The n-type metal conductor 132 having pure electron carriers refers to a general metal conductor that has no intrinsic energy level. In this configuration, carriers generated from photo-induction, that is, holes, are formed due to the p-type metal conductor which is an MIT material, and thus the solar cell 100d can function as a solar cell.

Other features of the solar cell 100d are the same as the solar cell 100b described with reference to FIG. 6, and thus a description thereof will be omitted here.

The solar cells 100, 100a, 100b, 100c, and 100d according to various embodiments are described above. Hereinafter, representative structures of the solar cells that can be practically used will be described.

That is, the solar cells may have one of the following structures:

glass substrate/Ni (or Mo, Al)/CuS/Cu₂S/CdS/ZnO/Au (or Al),

glass substrate/Ni (or Mo, Al)/CuSe/Cu₂Se/GaSe/InSe/ZnO/Au (or Al),

glass substrate/Ni (or Mo, Al)/CuTe/Cu₂Te/GaSe/InSe/ZnO/Au (or Al),

glass substrate/Ni (or Mo, Al)/CuTe/Cu₂Te/GaSe/CdS/ZnO/Au (or Al), and

glass substrate/Ni (or Mo, Al)/CuTe/Cu₂Te/CdS/ZnO/Au (or Al).

When second, third, and fourth of the above structures of the solar cell are applied to the solar cell 100b with reference to FIG. 6, a glass substrate may correspond to the substrate 110, Ni (or Mo, Al) may correspond to the lower electrode 120, CuS or CuTe may correspond to the p-type metal conductor 130, Cu₂S or Cu₂Te may correspond to the buffer layer 135, a double layer of GaSe/InSe or GaSe/CdS may correspond to the n-type metal conductor 140, ZnO (or a transparent layer) may correspond to the anti-reflection layer 150, and Au (or Al) may correspond to the upper electrode 160.

Also, in the case of first and fifth of the above structures, the n-type metal conductor 140 of the MIT material of FIG. 6 is replaced with an n-type metal conductor having pure electron carriers. Thus, the glass substrate may correspond to the substrate 110, Ni (or Mo, Al) may correspond to the lower electrode 120, CuS or CuTe may correspond to the p-type metal conductor 130, Cu₂S or Cu₂Te may correspond to the buffer layer 135, CdS may correspond to the n-type metal conductor having pure electron carriers, ZnO (or a transparent layer) may correspond to the anti-reflection layer 150, and Au (or Al) may correspond to the upper electrode 160.

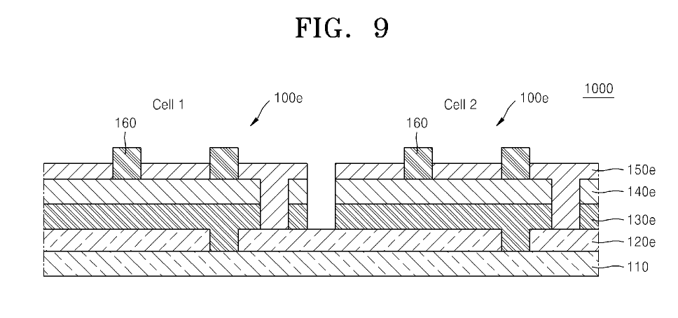

FIG. 9 is a cross-sectional view illustrating a solar cell module 1000 including a photo-induced MIT material complex according to an embodiment of the present invention.

Referring to FIG. 9, the solar cell module 1000 according to the current embodiment has a structure in which a plurality of solar cells 100e are connected serially. When forming a battery having a large surface area, the efficiency of the battery may generally decrease due to a surface effect. In order to prevent the surface effect, the battery may be manufactured individually in separate forms.

As illustrated in FIG. 9, lower electrodes 120e of the solar cells 100e are separated via p-type metal conductors 130e. That is, the lower electrodes 120e are separated from one another by extending a portion of the p-type metal conductors 130e onto a substrate 110. If the p-type metal conductors 130e and n-type metal conductors 140e change positions and thus the n-type metal conductors 140e are disposed on the lower electrodes 120e, the lower electrodes 120e may then obviously be separated by the n-type metal conductors 140e.

MIT material thin layers, that is, the p-type metal conductors 130e and the n-type metal conductors 140e are also separated via anti-reflection layers 150e. That is, predetermined portions of the anti-reflection layer 150e are extended onto the lower electrodes 120e, thereby separating the MIT material thin layers from one another. If a buffer layer is present, the buffer layer needs to be separated as well.

The solar cells 100e are separated so as to be disposed individually. That is, by separately forming an MIT material thin layers and a buffer layer in a solar cell from an MIT material thin layers and a buffer layer of another solar cell, the solar cells are separated from one another. Meanwhile, as illustrated in FIG. 9, the solar cells 100e are serially connected to one another via the lower electrodes 120e.

The solar cell module 1000 according to the current embodiment of the present invention has a large surface with an increased degree of integration and prevents the surface effect. Thus the efficiency of the solar cells can be maximized.

According to the photo-induced MIT material complex for a solar cell and the solar cell including the MIT material complex according to the present invention, charges of an intrinsic energy level instead of an impurity level are induced as carriers by light, in an insulator or a semiconductor that has a metallic electronic structure and an intrinsic energy level, and thus the number of carriers is remarkably increased compared to a semiconductor solar cell that uses an impurity level. Accordingly, a solar cell having high efficiency can be realized.

Also, in the solar cell module including the photo-induced MIT material complex according to the present invention, a plurality of the solar cells are connected serially but are individually separated from one another as individual batteries in order to prevent a surface effect, thereby maximizing the efficiency of the solar cells.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A photo-induced metal-insulator-transition (MIT) material complex for a solar cell, the photo-induced MIT material complex comprising:
an n-type (or electron-type) metal conductor that has a metallic electronic structure and undergoes MIT due to light, wherein carriers of the n-type metal conductor are electrons induced by light; and
a p-type (hole type) metal conductor that has a metallic electronic structure and undergoes MIT due to light, wherein carriers of the p-type metal conductor are holes induced by light,
wherein the photo-induced MIT material complex is formed by bonding the n-type and p-type metal conductors, and as light is incident on the bonded n-type and p-type metal conductors, the electrons and holes in an intrinsic energy level or gap become the carriers and a potential difference is generated.

2. The photo-induced MIT material complex of claim 1, wherein the p-type metal conductor is formed by stacking at least two p-type metal conductor thin films having different intrinsic energy levels, and the n-type metal conductor is formed by stacking at least two n-type metal conductor thin films having different intrinsic energy levels.

3. The photo-induced MIT material complex of claim 1, wherein the p-type metal conductor is a compound including Group I+VI elements or Group II+V elements of the periodic table.

4. The photo-induced MIT material complex of claim 1, wherein the p-type metal conductor is a compound including Group I+VI elements of the periodic table and comprises at least one selected from the group consisting of CuS, CuSe, CuTe, AgS, AgSe, and AgTe.

5. The photo-induced MIT material complex of claim 1, wherein the p-type metal conductor is a compound including Group I+VI elements of the periodic table and a Group V element below a critical density is added to the compound including Group I+VI elements.

6. The photo-induced MIT material complex of claim 1, wherein the p-type metal conductor is a compound including Group II+V elements of the periodic table and a Group IV element below a critical density is added to the compound including Group II+V elements.

7. The photo-induced MIT material complex of claim 1, wherein the n-type metal conductor is a compound including Group III+VI elements or Group IV+V elements of the periodic table.

8. The photo-induced MIT material complex of claim 1, wherein the n-type metal conductor is a compound including Group III+VI elements of the periodic table and comprises at least one selected from the group consisting of BS, AlS, GaS, InS, BSe, AlSe, GaSe, InSe, BTe, AlTe, GaTe, and InTe.

9. The photo-induced MIT material complex of claim 1, wherein the n-type metal conductor is a compound including Group III+VI elements of the periodic table and a Group II element below a critical density is added to the compound including Group III+VI elements.

10. The photo-induced MIT material complex of claim 1, wherein the n-type metal conductor is a compound including Group IV+V elements of the periodic table and a Group III element below a critical density is added to the compound including Group IV+V elements.

11. The photo-induced MIT material complex of claim 1, wherein the p-type metal conductor comprises at least one of La₂CuO₄, Ce₂CuO₄, Sc₂CuO₄, Y₂CuO₄, Ce₂CuSe₄, Sc₂CuSe₄, Y₂CuSe₄, Ce₂CuTe₄, Sc₂CuTe₄, and Y₂CuTe₄.

12. The photo-induced MIT material complex of claim 1, wherein the n-type metal conductor comprises at least one of VO₂, BaBiO₃, and LaMnO₃.

13. The photo-induced MIT material complex of claim 1, wherein the MIT material complex further comprises a buffer layer between the n-type metal conductor and the p-type metal conductor.

14. A solar cell comprising:
a substrate;
a lower electrode formed on the substrate;
the photo-induced MIT material complex of claim 1 formed on the lower electrode;
an anti-reflection layer formed on the MIT material complex; and
an upper electrode that is formed to pass through the anti-reflection layer and to contact the MIT material complex.

15. The solar cell of claim 14, wherein the p-type metal conductor is formed by stacking at least two p-type metal conductor thin films having different intrinsic energy levels, and
the n-type metal conductor is formed by stacking at least two n-type metal conductor thin films having different intrinsic energy levels.

16. The solar cell of claim 14, wherein the p-type metal conductor is a compound including Group I+VI elements or Group II+V elements of the periodic table, and
the n-type metal conductor is a compound including Group III+VI elements or Group IV+V elements of the periodic table.

17. The solar cell of claim 14, wherein the MIT material complex is formed on the lower electrode in the order of the n-type metal conductor and the p-type metal conductor or in the order of the p-type metal conductor and the n-type metal conductor.

18. The solar cell of claim 14, wherein the MIT material complex further comprises a buffer layer between the n-type metal conductor and the p-type metal conductor.

19. The solar cell of claim 18, wherein the buffer layer comprises a compound including at least one of Group II+VI, Group III+V, and Group IV elements of the periodic table.

20. The solar cell of claim 18, wherein the buffer layer comprises a Group 2I+VI metal compound of the periodic table, and the Group 2I+VI metal compound is at least one selected from the group consisting of Cu₂S, Ag₂S, Cu₂Se, Ag₂Se, Cu₂Te, and Ag₂Te.

21. The solar cell of claim 18, wherein the buffer layer comprises a Group 2III+3VI metal compound of the periodic table, and the Group 2III+3VI metal compound is at least one selected from the group consisting of B₂S₃, Al₂S₃, Ga₂S₃, B₂Se₃, Al₂Se₃, Ga₂Se₃, In₂Se₃, B₂Te₃, Al₂Te₃, Ga₂Te₃, and In₂Te₃.

22. The solar cell of claim 14, wherein the anti-reflection layer comprises at least two anti-reflection thin films formed of different materials.

23. The solar cell of claim 14, wherein the anti-reflection layer comprises at least one of a transparent compound, ZnO, TiO₂, BaTiO₃, and ZrO₂, which have an energy level of 3 eV or greater.

24. The solar cell of claim 14, wherein the substrate comprises one of Si, glass, a stainless iron plate, a silicon-on-insulator (SOI), and a compound substrate.

25. The solar cell of claim 14, wherein the lower and upper electrodes comprise a monoatomic metal electrode or a compound electrode.

26. The solar cell of claim 14, wherein the MIT material complex further comprises a buffer layer between the n-type metal conductor and the p-type metal conductor, and the solar cell is one of
a solar cell including a glass substrate/Ni (or Mo, Al)/CuSe/Cu₂Se/GaSe/InSe/ZnO (or transparent layer)/Au (or Al) that are sequentially formed,
a solar cell including a glass substrate/Ni (or Mo, Al)/CuTe/Cu₂Te/GaSe/InSe/ZnO (or transparent layer)/Au (or Al) that are sequentially formed, and
a solar cell including a glass substrate/Ni (or Mo, Al)/CuTe/Cu₂Te/GaSe/CdS/ZnO (or transparent layer)/Au (or Al) that are sequentially formed, and
the glass substrate corresponds to the substrate, Ni (or Mo, Al) corresponds to the lower electrode, CuSe or CuTe corresponds to the p-type metal conductor, Cu₂Se or Cu₂Te corresponds to the buffer layer, a double layer of GaSe/InSe or GaSe/CdS corresponds to the n-type metal conductor, ZnO (or transparent layer) corresponds to the anti-reflection layer, and Au (or Al) corresponds to the upper electrode.

27. A solar cell comprising:
a substrate;
a lower electrode formed on the substrate;
a photo-induced MIT material complex to be used to form a solar cell, which is formed on the lower electrode and comprises an n-type metal conductor and a p-type metal conductor;
an anti-reflection layer formed on the MIT material complex; and
an upper electrode that is formed to pass through the anti-reflection layer and to contact the MIT material complex,
wherein the n-type metal conductor has no intrinsic energy level and carriers of the n-type metal conductor are pure electrons, and
the p-type metal conductor is an insulator or semiconductor that has a metallic electronic structure and undergoes MIT due to light, and has an intrinsic energy level, and carriers of the p-type metal conductor are holes induced by light, and
the MIT material complex is formed by bonding the n-type and p-type metal conductors, and as light is incident on the n-type and p-type metal conductors, the pure electrons and the holes in the intrinsic energy level become the carriers and a potential difference is generated.

28. The solar cell of claim 27, wherein the MIT material complex further comprises a buffer layer between the n-type metal conductor and the p-type metal conductor, and the solar cell is one of
a solar cell including a glass substrate/Ni (or Mo, Al)/CuS/Cu₂S/CdS/ZnO (or transparent layer)/Au (or Al) that are sequentially formed, and
a solar cell including a glass substrate/Ni (or Mo, Al)/CuTe/Cu₂Te/CdS/ZnO (or transparent layer)/Au (or Al) that are sequentially formed, and
the glass substrate corresponds to the substrate, Ni (or Mo, Al) corresponds to the lower electrode, CuS or CuTe corresponds to the p-type metal conductor, Cu₂S or Cu₂Te corresponds to the buffer layer, the CdS corresponds to the n-type metal conductor, ZnO (or transparent layer) corresponds to the anti-reflection layer, and Au (or Al) corresponds to the upper electrode.

29. A solar cell module which is formed of at least two of the solar cell of claim 27, wherein the solar cells are connected serially.

30. The solar cell module of claim 29, wherein all of the solar cells of the solar cell module are arranged on the substrate, and the lower electrodes of the solar cells are separated from one another by a portion of the p-type metal conductor or a portion of the n-type metal conductor of the MIT material complex, which is extended onto the substrate, and
the MIT material complexes in each of the solar cells are separated from one another by a predetermined portion of the anti-reflection layer, which is extended onto the lower electrodes, and structures formed on the lower electrodes are separated by a predetermined distance apart from one another to separate the solar cells in the solar cell module from one another, and the solar cells are serially connected via the lower electrodes.
